(19) United States
(12) Patent Application Publication
(10) Pub. No.: US 2026/0134323 A1
(43) Pub. Date: May 14, 2026

(54) SUPERCONDUCTING QUANTUM CIRCUIT, QUANTUM BIT, QUANTUM COMPUTER, AND MANUFACTURING METHOD

(71) Applicant: NEC Corporation, Minato-ku, Tokyo (JP)

(72) Inventors: Tomohiro YAMAJI, Tokyo (JP); Tetsuro SATO, Tokyo (JP)

(73) Assignee: NEC Corporation, Minato-ku, Tokyo (JP)

(21) Appl. No.: 18/959,969

(22) Filed: Nov. 26, 2024

(30) Foreign Application Priority Data
Dec. 20, 2023 (JP) 2023-215224

(51) Int. Cl. G06N 10/40; H10N 60/12

(52) U.S. Cl. CPC G06N 10/40; H10N 60/12

(57) ABSTRACT

A superconducting quantum circuit includes a substrate, a superconductor layer that is laminated on the substrate and includes a main pattern and a stretched pattern, a first deposition pattern having a portion that is laminated on the superconductor layer, a second deposition pattern having an overlap portion with the first deposition pattern, and a Josephson junction in the overlap portion, in which the stretched pattern is connected with at least one of the first deposition pattern or the second deposition pattern.

### CROSS-REFERENCE TO RELATED APPLICATION

Priority is claimed on Japanese Patent Application No. 2023-215224, filed December 20, 2023, the content of which is incorporated herein by reference.

### BACKGROUND ART

The present disclosure relates to a superconducting quantum circuit, a quantum bit, a quantum computer, and a manufacturing method.

It is known that a superconducting quantum circuit is used in a quantum device mounted in a quantum computer or the like.

As such a superconducting quantum circuit, for example, PCT International Publication No. WO2022/118463 (hereinafter referred to as Patent Document 1) describes a superconducting quantum circuit in which a conductor layer and two deposition patterns are formed of a superconducting material.

### SUMMARY

In the superconducting quantum circuit described in Patent Document 1, a Josephson junction is formed by obliquely depositing two deposition patterns on a substrate on which the conductor layer is formed.

Note that, in the superconducting quantum circuit disclosed in Patent Document 1, the deposition pattern may be longer depending on a circuit configuration. If a portion of the deposition pattern is longer, for example, the characteristics of the superconducting quantum circuit may be degraded. For this reason, it is difficult to form the superconducting quantum circuit disclosed in Patent Document 1 with the deposition pattern.

An example object of the present disclosure is to provide a superconducting quantum circuit, a quantum bit, a quantum computer, and a manufacturing method that solve the above-described problem.

A superconducting quantum circuit according to an example aspect of the present disclosure includes a substrate, a superconductor layer that is laminated on the substrate and includes a main pattern and a stretched pattern, a first deposition pattern having a portion that is laminated on the superconductor layer, a second deposition pattern having an overlap portion with the first deposition pattern, and a Josephson junction in the overlap portion, in which the stretched pattern is connected with at least one of the first deposition pattern or the second deposition pattern.

A manufacturing method according to an example aspect of the present disclosure includes laminating a portion of a first deposition pattern on a superconductor layer that is laminated on a substrate and includes a main pattern and a stretched pattern, oxidizing a surface of the first deposition pattern, and forming a second deposition pattern, in which a Josephson junction is formed in an overlap portion of the first deposition pattern and the second deposition pattern, and in which the stretched pattern is connected with at least one of the first deposition pattern or the second deposition pattern.

### BRIEF DESCRIPTION OF THE DRAWINGS

FIG. 1 is a block diagram of a quantum computer according to the present disclosure.

FIG. 2 is a plan view of a superconducting quantum circuit according to the present disclosure.

FIG. 3 is an enlarged view of a III portion of FIG. 2.

FIG. 4 is a flowchart of a manufacturing method according to the present disclosure.

FIG. 5 is a plan view illustrating an example of a mask pattern that is used in an oblique irradiation method.

FIG. 6 is a plan view of a deposition pattern that is deposited by the oblique irradiation method using the mask pattern of FIG. 5.

FIG. 7 is a plan view of a mask pattern that is used in a manufacturing method according to the present disclosure.

FIG. 8 is a schematic view illustrating an oblique deposition method according to Comparative Example 1.

FIG. 9 is a plan view of a superconducting quantum circuit according to Comparative Example 2.

FIG. 10 is a plan view of a superconducting quantum circuit according to the present disclosure.

FIG. 11 is an enlarged view of an XI portion of FIG. 10.

FIG. 12 is a plan view of a superconducting quantum circuit according to the present disclosure.

FIG. 13 is a flowchart illustrating a manufacturing method according to the present disclosure.

### EXAMPLE EMBODIMENT

Hereinafter, some example embodiments according to the present disclosure will be described with reference to the drawings.

### Configuration of Quantum Computer

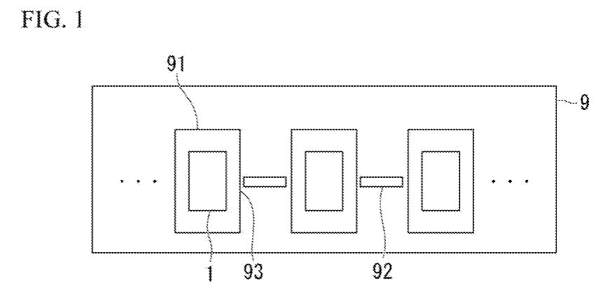

As illustrated in FIG. 1, a quantum computer 9 includes a plurality of quantum bits 91 and a plurality of couplers 92.

The quantum computer 9 may be an annealing quantum computer or may be a gate quantum computer.

The plurality of couplers 92 couple the plurality of quantum bits 91.

### Configuration of Quantum Bit

Each quantum bit 91 includes a superconducting quantum circuit 1 and a coupling portion 93.

Each quantum bit 91 is coupled to another quantum bit 91 via the coupler 92 coupled to the coupling portion 93. Note that the coupler 92 is not essential, and for example, the plurality of quantum bits 91 may have a structure in which two quantum bits are coupled only with the coupling portion 93 without using the coupler 92.

### Configuration of Superconducting Quantum Circuit

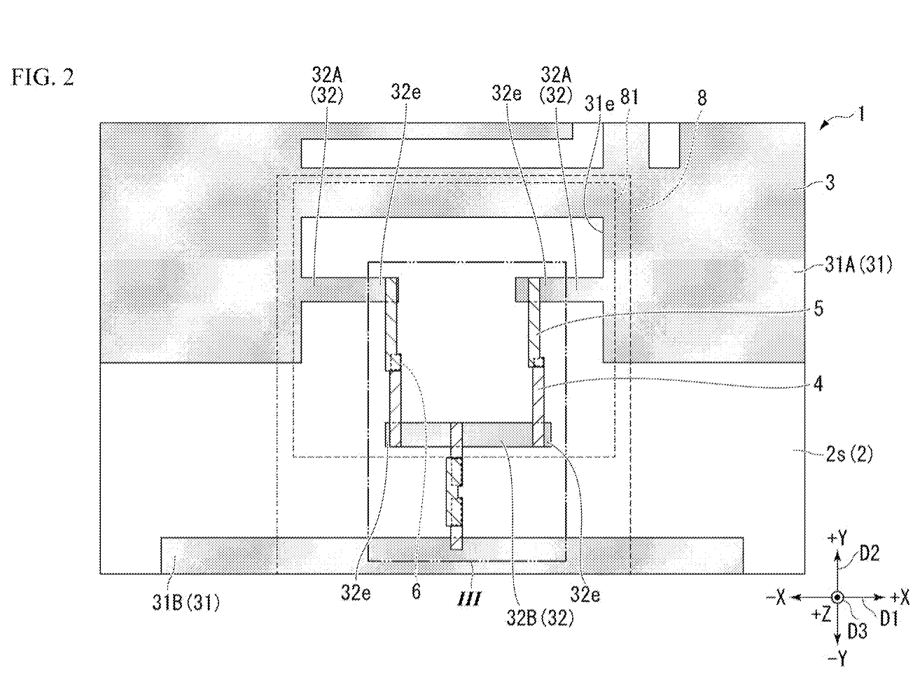

As illustrated in FIG. 2, the superconducting quantum circuit 1 includes a substrate 2, a superconductor layer 3, a first deposition layer 4, and a second deposition layer 5.

The superconducting quantum circuit 1 has a plurality of Josephson junctions (hereinafter, also referred to as "JJ") 6 for implementing a structure of superconductor-insulator thin film-superconductor.

### Configuration of Substrate

The substrate 2 is provided with each pattern of the superconducting quantum circuit 1.

The substrate 2 has a substrate surface 2s.

In the substrate surface 2s, there are a portion where each pattern is formed and an exposed portion.

For example, the substrate 2 may be formed of a material such as silicon, sapphire, or a compound semiconductor.

For example, the substrate 2 is formed of a single crystal, polycrystal, or amorphous substrate.

For example, the substrate 2 may be a high-resistance semiconductor substrate.

Hereinafter, a direction in which each pattern is laminated is referred to as a Z direction. One direction in the substrate surface 2s is referred to as an X direction. A direction intersecting the X direction in the substrate surface 2s is referred to as a Y direction. One side in the X direction is referred to as a +X direction, and the other side in the X direction is referred to as a -X direction. One side in the Y direction is referred to as a +Y direction, and the other side in the Y direction is referred to as a -Y direction. One side in the Z direction is referred to as a +Z direction, and the other side in the Z direction is referred to as a -Z direction. The X direction is also referred to as a deposition direction D1. The Y direction is also referred to as a connection direction D2. The Z direction is also referred to as a lamination direction D3.

For example, the X direction, the Y direction, and the Z direction are directions perpendicular to each other. For example, the substrate surface 2s may be a surface along an XY plane and a surface toward the +Z direction. For example, the +Z direction may be an upward direction.

Hereinafter, each pattern shape or the position of each pattern is a shape or a position as viewed from the Z direction unless otherwise specified.

### Configuration of Superconductor Layer

The superconductor layer 3 is laminated over the substrate surface 2s.

The superconductor layer 3 includes a plurality of surface patterns 31 (main pattern) and a plurality of stretched patterns 32.

For example, the superconductor layer 3 may be formed by, for example, sputtering, deposition, or chemical vapor deposition (CVD).

For example, each pattern of the superconductor layer 3 may be patterned by reactive ion etching or wet etching.

For example, each pattern of the superconductor layer 3 may be formed of Nb as a superconductor.

### Surface Pattern

The plurality of surface patterns 31 include a ground pattern 31A and an electrode pattern 31B.

Each surface pattern 31 is a planar pattern.

For example, each pattern of the surface pattern 31 may be a pattern including at least a rectangular region having a longitudinal dimension and a lateral dimension greater than each stretched width (a dimension in a direction perpendicular to an extension direction) of the plurality of stretched patterns 32.

### Stretched Pattern

Each stretched pattern 32 has a stretched end 32e at an extension end.

For example, each stretched pattern 32 has a band shape extending in one direction, for example, the X direction.

The plurality of stretched patterns 32 include a pair of protrusion patterns 32A and an island pattern 32B.

Each of the pair of protrusion patterns 32A is a pattern that is continuous to the ground pattern 31A.

Each of the pair of protrusion patterns 32A protrudes from the ground pattern 31A in the X direction to have the stretched end 32e as a protrusion end.

In the present example embodiment, the protrusion ends of the pair of protrusion patterns 32A face each other.

Specifically, out of the pair of protrusion patterns 32A, the protrusion pattern 32A on the -X direction side protrudes from the ground pattern 31A in the +X direction. Out of the pair of protrusion patterns 32A, the protrusion pattern 32A on the +X direction side protrudes from the ground pattern 31A in the -X direction.

For example, the pair of protrusion patterns 32A may have the same length in the X direction.

For example, the pair of protrusion patterns 32A may have the same width in the Y direction.

For example, each protrusion pattern 32A may protrude from an end side 31e of the ground pattern 31A extending in the Y direction with a width in the Y direction smaller than a length of the end side 31e in the Y direction.

The island pattern 32B is separated from the plurality of surface patterns 31.

In the present example embodiment, the island pattern 32B are separated from the ground pattern 31A and the electrode pattern 31B.

For example, the island pattern 32B may be separated in the -Y direction with respect to the pair of protrusion patterns 32A.

As viewed from the X direction, for example, the island pattern 32B may be positioned between the ground pattern 31A and the electrode pattern 31B, and may be separated from the ground pattern 31A and the electrode pattern 31B.

For example, the island pattern 32B may extend between the pair of protrusion patterns 32A facing each other such that both ends of the island pattern 32B overlap the protrusion ends of the pair of protrusion patterns 32A facing each other as viewed from the Y direction.

For example, the island pattern 32B may have the same width in the Y direction as the width in the Y direction of each protrusion pattern 32A.

### Configuration of First Deposition Layer

The first deposition layer 4 is a pattern for bridging the ground pattern 31A, the island pattern 32B, and the electrode pattern 31B via the Josephson junctions 6 along with the second deposition layer 5.

The first deposition layer 4 is partially laminated over the superconductor layer 3.

For example, the first deposition layer 4 is a deposition layer deposited over the superconductor layer 3 from an oblique direction with respect to the Z direction by an oblique deposition method.

For example, the first deposition layer 4 may be formed of Al as a superconductor.

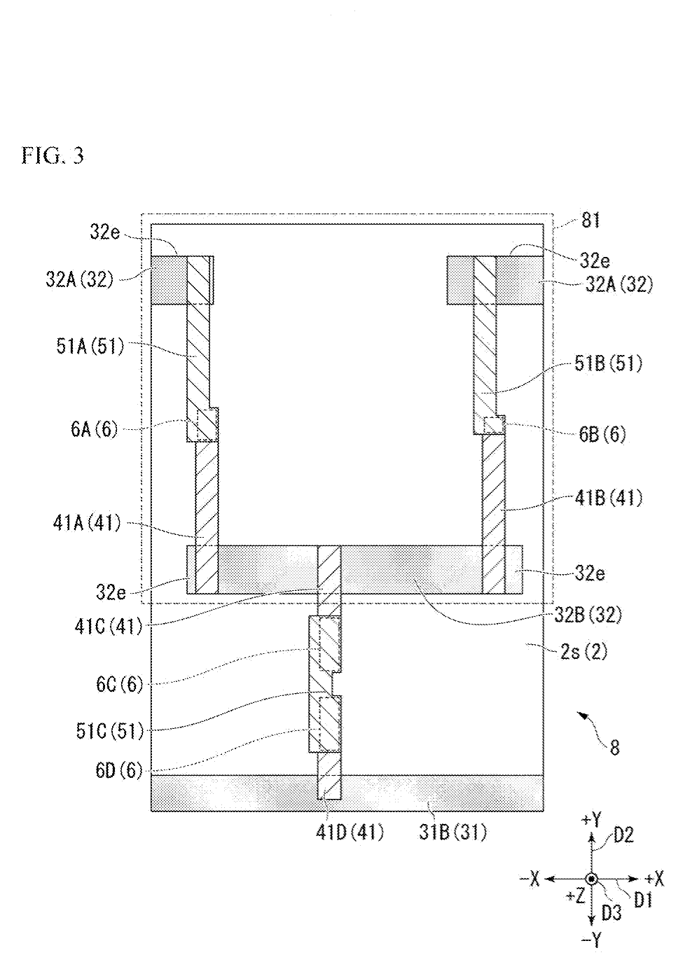

As illustrated in FIG. 3, the first deposition layer 4 includes a plurality of first deposition patterns 41.

A portion of each first deposition pattern 41 is laminated over the superconductor layer 3.

For example, the plurality of first deposition patterns 41 may include a first deposition pattern 41A, a first deposition pattern 41B, a first deposition pattern 41C, and a first deposition pattern 41D.

Each of the first deposition pattern 41A, the first deposition pattern 41B, the first deposition pattern 41C, and the first deposition pattern 41D has a band shape extending in the Y direction.

The first deposition pattern 41A and the first deposition pattern 41B are positioned at the center in the Y direction and are arranged in the X direction separately from each other.

A portion of the first deposition pattern 41A on the -Y direction side is electrically connected to the island pattern 32B by overlapping the stretched end 32e of the island pattern 32B on the -X direction side.

For example, with respect to an overlap portion of the first deposition pattern 41A and the stretched end 32e of the island pattern 32B, the stretched end 32e of the island pattern 32B on the -X direction side may further extend from the overlap portion in the -X direction.

A portion of the first deposition pattern 41B on the -Y direction side is electrically connected to the island pattern 32B by overlapping the stretched end 32e of the island pattern 32B on the +X direction side.

For example, with respect to an overlap portion of the first deposition pattern 41B and the stretched end 32e of the island pattern 32B, the stretched end 32e of the island pattern 32B on the +X direction side may further extend from the overlap portion in the +X direction.

The first deposition pattern 41C and the first deposition pattern 41D are positioned on the -Y direction side with respect to the first deposition pattern 41A and the first deposition pattern 41B.

The first deposition pattern 41C and the first deposition pattern 41D are arranged in the Y direction separately from each other.

As viewed from the Y direction, the first deposition pattern 41C and the first deposition pattern 41D are positioned between the first deposition pattern 41A and the first deposition pattern 41B, and are separated from the first deposition pattern 41A and the first deposition pattern 41B.

A portion of the first deposition pattern 41C on the +Y direction side is electrically connected to the island pattern 32B by overlapping a central portion of the island pattern 32B in the X direction.

A portion of the first deposition pattern 41D on the -Y direction side is electrically connected to the electrode pattern 31B by overlapping a central portion of the electrode pattern 31B in the X direction.

### Configuration of Second Deposition Layer

The second deposition layer 5 is partially laminated over the first deposition layer 4.

For example, the second deposition layer 5 may be a deposition layer deposited over the superconductor layer 3 from an oblique direction different from that of the first deposition layer 4 with respect to the Z direction following the deposition of the first deposition layer 4 by the oblique deposition method.

For example, the second deposition layer 5 may be formed of Al as a superconductor.

The second deposition layer 5 includes a plurality of second deposition patterns 51.

A portion of each second deposition pattern 51 is laminated over the corresponding first deposition pattern 41.

For example, the plurality of second deposition patterns 51 may include a second deposition pattern 51A, a second deposition pattern 51B, and a second deposition pattern 51C.

Each of the second deposition pattern 51A, the second deposition pattern 51B, and the second deposition pattern 51C has a band shape extending in the Y direction.

The second deposition pattern 51A and the second deposition pattern 51B are positioned on the +Y direction side with respect to the first deposition pattern 41A and the first deposition pattern 41B.

The second deposition pattern 51A and the second deposition pattern 51B are arranged in the X direction separately from each other.

The second deposition pattern 51A partially overlaps the first deposition pattern 41A to be shifted in the +Y direction with respect to the first deposition pattern 41A.

The second deposition pattern 51B partially overlaps the first deposition pattern 41B to be shifted in the +Y direction with respect to the first deposition pattern 41B.

A portion of the second deposition pattern 51A on the +Y direction side is electrically connected to the protrusion pattern 32A on the -X direction side by overlapping a portion of the stretched end 32e of the protrusion pattern 32A on the -X direction side out of the pair of protrusion patterns 32A.

For example, with respect to an overlap portion of the second deposition pattern 51A and the stretched end 32e of the protrusion pattern 32A, the stretched end 32e of the protrusion pattern 32A on the -X direction side may further extend from the overlap portion in the +X direction.

A portion of the second deposition pattern 51A on the -Y direction side is electrically connected to the first deposition pattern 41A via the Josephson junction 6 by overlapping a portion of the first deposition pattern 41A on the +Y direction side.

For example, a width in the X direction of the portion of the second deposition pattern 51A on the -Y direction side may be wider than a width in the X direction of another portion of the second deposition pattern 51A in the portion overlapping the first deposition pattern 41A.

For example, the width in the X direction of the portion of the second deposition pattern 51A on the -Y direction side may be wider than a width in the X direction of the first deposition pattern 41A in the portion overlapping the first deposition pattern 41A.

A portion of the second deposition pattern 51B on the +Y direction side is electrically connected to the protrusion pattern 32A on the +X direction side by overlapping a portion of the stretched end 32e of the protrusion pattern 32A on the +X direction side out of the pair of protrusion patterns 32A.

For example, with respect to an overlap portion of the second deposition pattern 51B and the stretched end 32e of the protrusion pattern 32A, the stretched end 32e of the protrusion pattern 32A on the +X direction side may further extend from the overlap portion in the -X direction.

A portion of the second deposition pattern 51B on the -Y direction is electrically connected to the first deposition pattern 41B via the Josephson junction 6 by overlapping a portion of the first deposition pattern 41B on the +Y direction side.

For example, a width in the X direction of the portion of the second deposition pattern 51B on the -Y direction side may be wider than a width in the X direction of another portion of the second deposition pattern 51B in the portion overlapping the first deposition pattern 41B.

For example, the width in the X direction of the portion of the second deposition pattern 51B on the -Y direction side may be wider than the width in the X direction of the first deposition pattern 41B in the portion overlapping the first deposition pattern 41B.

The second deposition pattern 51C partially overlaps the first deposition pattern 41C to be shifted in the -Y direction with respect to the first deposition pattern 41C.

A portion of the second deposition pattern 51C on the +Y direction side is electrically connected to the first deposition pattern 41C via the Josephson junction 6 by overlapping a portion of the first deposition pattern 41C on the -Y direction side.

For example, the width in the X direction of the portion of the second deposition pattern 51C on the +Y direction side may be wider than the width in the X direction of a central portion of the second deposition pattern 51C in the Y direction in the portion overlapping the first deposition pattern 41C.

For example, the width in the X direction of the portion of the second deposition pattern 51C on the +Y direction side may be wider than the width in the X direction of the first deposition pattern 41C in the portion overlapping the first deposition pattern 41C.

The second deposition pattern 51C partially overlaps the first deposition pattern 41D to be shifted in the +Y direction with respect to the first deposition pattern 41D.

A portion of the second deposition pattern 51C on the -Y direction side is electrically connected to the first deposition pattern 41D via the Josephson junction 6 by overlapping a portion of the first deposition pattern 41D on the +Y direction side.

For example, the width in the X direction of the portion of the second deposition pattern 51C on the -Y direction side may be wider than the width in the X direction of the central portion of the second deposition pattern 51C in the Y direction in the portion overlapping the first deposition pattern 41D.

For example, the width in the X direction of the portion of the second deposition pattern 51C on the -Y direction side may be wider than the width in the X direction of the first deposition pattern 41D in the portion overlapping the first deposition pattern 41D.

### Configuration of Josephson Junction

The plurality of Josephson junctions 6 include a first Josephson junction 6A, a second Josephson junction 6B, a third Josephson junction 6C, and a fourth Josephson junction 6D.

The first Josephson junction 6A is formed in a portion where the first deposition pattern 41A overlaps the second deposition pattern 51A.

The second Josephson junction 6B is formed in a portion where the first deposition pattern 41B overlaps the second deposition pattern 51B.

The third Josephson junction 6C is formed in a portion where the first deposition pattern 41C overlaps the second deposition pattern 51C.

The fourth Josephson junction 6D is formed in a portion where the first deposition pattern 41D overlaps the second deposition pattern 51C.

### Configuration of Nonlinear Inductor and Superconducting Quantum Interference Device

In the superconducting quantum circuit 1, the superconductor layer 3, the first deposition patterns 41, the second deposition patterns 51, and the Josephson junctions 6 are electrically connected to configure a SQUID (superconducting quantum interference device) 81 (SQUID sensor 81).

In the superconducting quantum circuit 1, a nonlinear inductor 8 including the SQUID 81 is configured.

The nonlinear inductor 8 and the SQUID 81 are specifically configured as follows.

The SQUID 81 includes the pair of protrusion patterns 32A, a pattern of a part of the ground pattern 31A, the island pattern 32B, the first deposition pattern 41A, the first deposition pattern 41B, the second deposition pattern 51A, the second deposition pattern 51B, the first Josephson junction 6A, and the second Josephson junction 6B.

In the SQUID 81, one of the pair of protrusion patterns 32A, the second deposition pattern 51A, the first Josephson junction 6A, the first deposition pattern 41A, the island pattern 32B, the first deposition pattern 41B, the second Josephson junction 6B, the second deposition pattern 51B, the other of the pair of protrusion patterns 32A, and the ground pattern 31A are electrically connected to draw a loop in this order.

The ground pattern 31A functions as a termination portion of the SQUID 81.

The nonlinear inductor 8 includes, in addition to the SQUID 81, the first deposition pattern 41C, the third Josephson junction 6C, the second deposition pattern 51C, the fourth Josephson junction 6D, the first deposition pattern 41D, and the electrode pattern 31B.

In the nonlinear inductor 8, the SQUID 81 and the third Josephson junction 6C are electrically connected in series via the first deposition pattern 41C.

In the nonlinear inductor 8, the third Josephson junction 6C and the fourth Josephson junction 6D are electrically connected in series via the second deposition pattern 51C.

In the nonlinear inductor 8, the fourth Josephson junction 6D and the electrode pattern 31B are electrically connected in series via the first deposition pattern 41D.

### (Steps of Manufacturing Method)

Hereinafter, a manufacturing method of the present example embodiment will be described.

The manufacturing method of the present example embodiment is a method for manufacturing the superconducting quantum circuit 1.

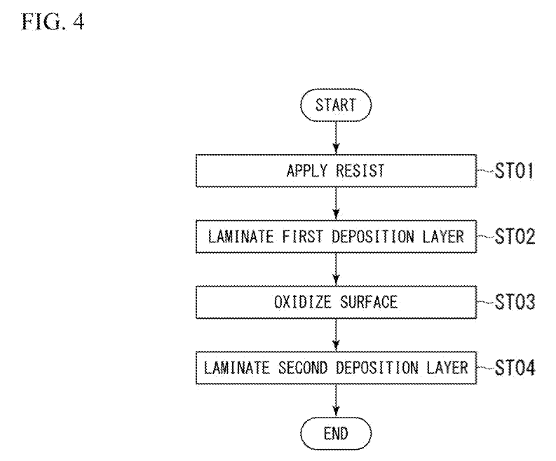

As illustrated in FIG. 4, first, a manufacturer applies resist on a substrate where the superconductor layer 3 is laminated over the substrate surface 2s, and further forms a mask pattern (ST01: application step).

Subsequently to the execution of ST01, the manufacturer laminates a portion of each first deposition pattern 41 over the superconductor layer 3 (ST02: first deposition step).

For example, in ST02, the manufacturer may deposit the first deposition layer 4 made of Al by an oblique deposition method described below.

Subsequently to the execution of ST02, the manufacturer oxidizes the surface of each first deposition pattern 41 (ST03: surface oxidization step).

For example, in ST03, AlOx having a prescribed film thickness may be formed on the surface of the first deposition layer 4 by thermally oxidizing the surface of the first deposition layer 4 made of Al.

Subsequently to the execution of ST03, the manufacturer laminates a portion of each second deposition pattern 51 over the related first deposition pattern 41 (ST04: second deposition step).

For example, in ST04, the manufacturer may deposit the second deposition layer 5 made of Al over the first deposition layer 4 by the oblique deposition method described below.

In the present example embodiment, with the execution of ST01 to ST04, the superconducting quantum circuit 1 that includes a superconducting quantum interference device 81 including the superconductor layer 3, the first deposition pattern 41, the second deposition pattern 51, and the Josephson junction 6 is formed.

Here, in an example of ST02 and ST04, each deposition layer is deposited using the oblique deposition method.

In the oblique deposition method, an emission direction of a superconducting material is tilted in the deposition direction D1 with respect to the Z direction.

In the oblique deposition method, the emission direction of the superconducting material is tilted to one side in the deposition direction D1 with respect to the Z direction in first deposition, and is tilted to the other side in the deposition direction D1 with respect to the Z direction in second deposition.

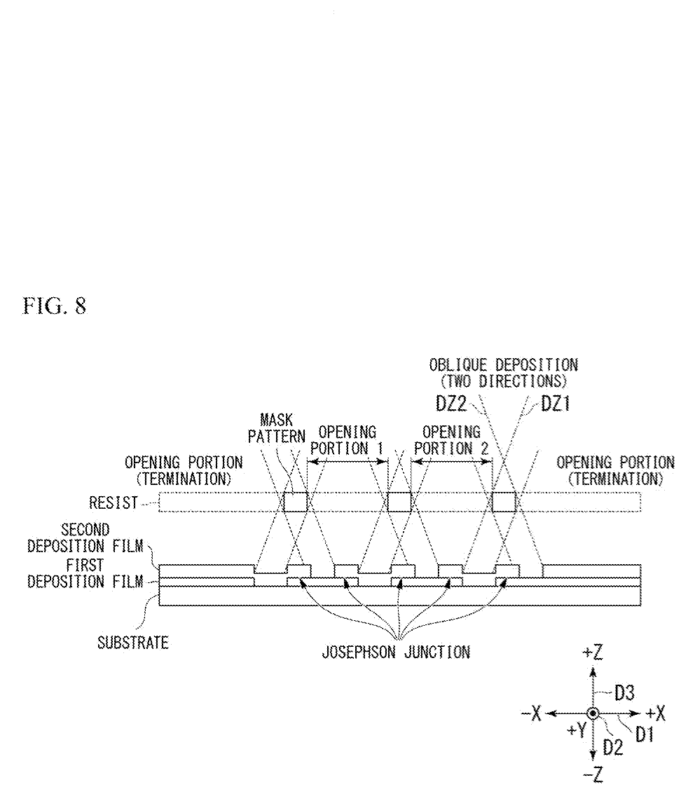

In the typical oblique deposition method, first, the manufacturer emits a superconducting material in a first irradiation direction DZ1 (see FIG. 8 described below) tilted in the -X direction with respect to the -Z direction and performs oblique deposition of a first deposition film. As a result, each pattern of the first deposition film is formed at a position shifted in the -X direction with respect to a position of each opening portion of resist in the X direction.

Subsequently, the manufacturer performs surface oxidization of the first deposition film, then, emits a superconducting material in a second irradiation direction DZ2 (see FIG. 8 described below) tilted in the +X direction with respect to the -Z direction, and performs oblique deposition of a second deposition film. As a result, each pattern of the second deposition film is formed at a position shifted in the +X direction with respect to a position of each opening portion of resist in the X direction.

In this case, the Josephson junction is formed in a portion where the first deposition film overlaps the second deposition film.

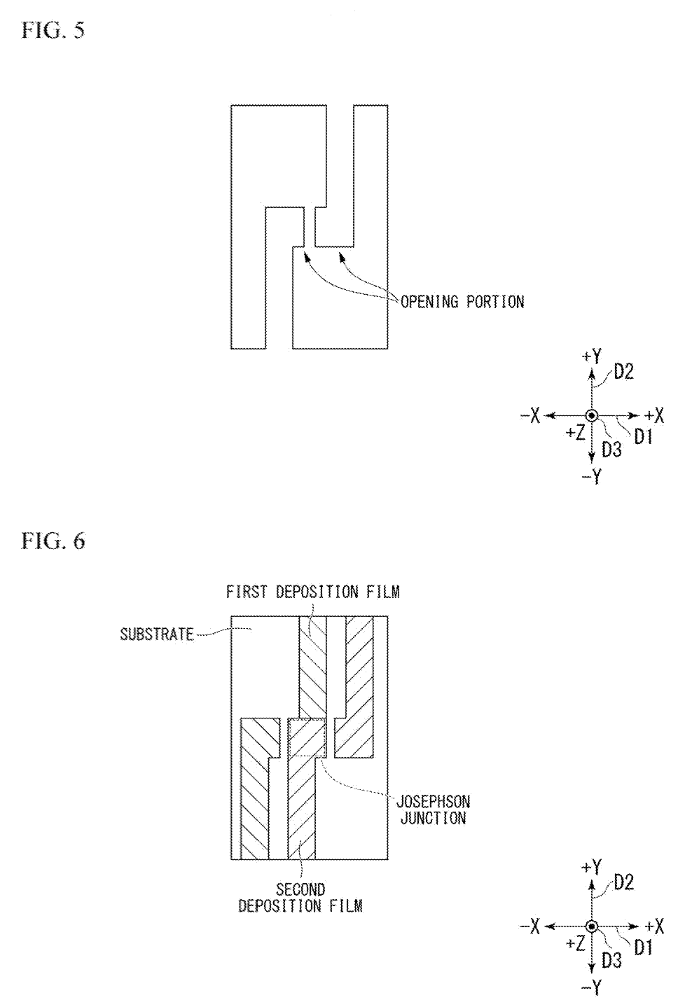

With such an oblique deposition method, the pattern of each deposition film as illustrated in FIG. 6 can be formed, for example, with the mask pattern as illustrated in FIG. 5.

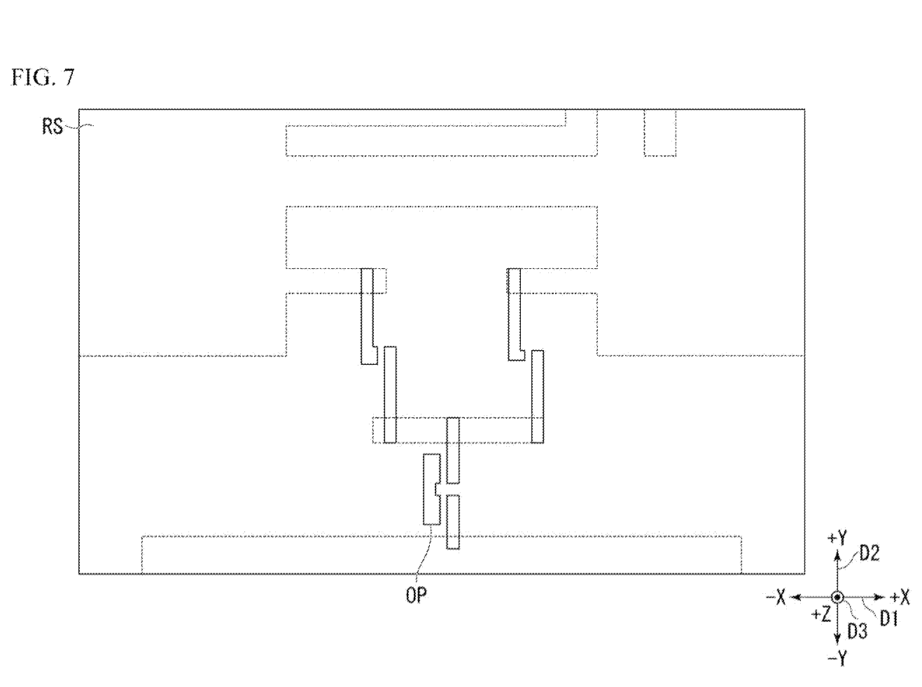

In the present example embodiment, each pattern as illustrated in FIGS. 1 and 2 is formed using resist RS having an opening portion OP as illustrated in FIG. 7.

According to the oblique deposition method, like the deposition patterns illustrated on right and left sides among the deposition patterns illustrated in FIG. 6, an isolated deposition pattern not involved in the Josephson junction is simultaneously deposited. For this reason, in a plan view of the superconducting quantum circuit according to the present disclosure including FIGS. 1 and 2, such an isolated deposition pattern not involved in the Josephson junction is omitted.

### Operation and Effects

With the superconducting quantum circuit 1 of the present example embodiment, the stretched patterns 32 of the superconductor layer 3 extend to the first deposition pattern 41 and the second deposition pattern 51.

For this reason, it is possible to configure the first deposition layer 4 and the second deposition layer 5 such that the first deposition pattern 41 and the second deposition pattern 51 are shortened.

Accordingly, the superconducting quantum circuit 1 is easily formed with the deposition patterns.

For example, as Comparative Example 1, as illustrated in FIG. 8, in using an oblique deposition method from two directions of a first irradiation direction DZ1 and a second irradiation direction DZ2, if there is an opening portion that is long in a deposition direction, a Josephson junction having about the same area as the opening portion is formed directly below the opening portion. While such a junction can be approximated as a simple superconducting wire because of a very large critical current value in proportion to the area, the behavior of the nonlinear inductor is likely to be separated from a design value.

A superconductor (hereinafter, also referred to as "SES") that is obliquely deposited via a step such as resist application is generally deteriorated in characteristic compared to a superconductor (hereinafter, also referred to as "GS") deposited on a surface of a high-resistance semiconductor substrate because of including a defect such as a resist residue.

Since a superconductor having a low superconducting transition temperature such as Al is used for the SES, the characteristics of the quantum circuit are also likely to be deteriorated due to quasiparticles, and it is desirable that the structure of the nonlinear inductor is as small as possible.

The superconducting quantum circuit is widely used as a quantum bit. While a Josephson parametric oscillator (JPO) that is a type of superconducting quantum circuit and is excited by periodic fluctuation of a resonant frequency at a frequency close to a double frequency of the resonant frequency is expected to be applied to a quantum annealer, low Kerr nonlinearity is required compared to a transmon quantum bit that is used in gate quantum calculation or the like.

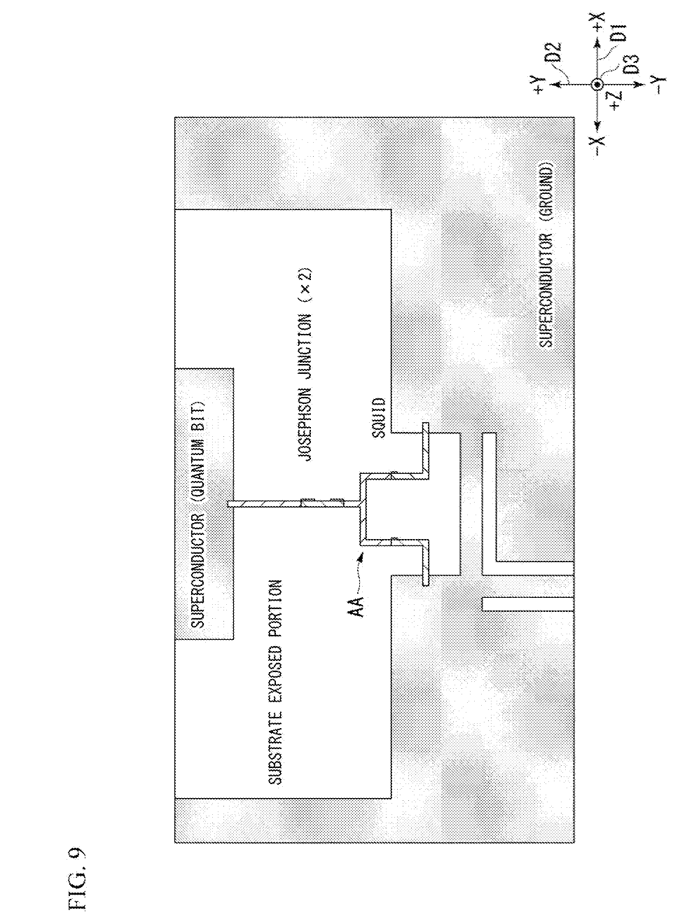

In reducing Kerr nonlinearity, as Comparative Example 2, it is effective for the superconducting quantum circuit to configure a nonlinear inductor with a SQUID and a JJ connected in series by deposition patterns as illustrated in FIG. 9.

Note that, if the SES by the series structure increases, like a deposition pattern AA illustrated in FIG. 9, in a deposition pattern that is formed by a long opening portion in a direction parallel to the deposition direction D1, a Josephson junction having about the same area as the opening portion inevitably occurs in a portion of the SQUID on the principle illustrated in FIG. 8.

In contrast to Comparative Example 1 and Comparative Example 2, in the superconducting quantum circuit 1 of the present example embodiment, for example, the nonlinear inductor including the SQUID and the JJ is not configured with only the SES to be obliquely deposited, and a termination portion or a coupling portion of the SQUID and the JJ is configured with the GS deposited on the substrate surface.

That is, the superconducting quantum circuit 1 of the present example embodiment is configured such that the nonlinear inductor has the island pattern of the GS and the protrusion pattern of GS in addition to the SES as illustrated in FIGS. 1 and 2.

For this reason, the superconducting quantum circuit 1 of the present example embodiment has a structure in which the superconducting quantum circuit and the ground are bridged by the nonlinear inductor in which the SQUID and the JJ are connected in series.

With such a structure, the SQUID and the JJ bridge the ground pattern, the island pattern, and the electrode pattern made of GS remaining within a high-resistance semiconductor exposed surface.

With this, in addition to reduction of the amount of the SES that can increase the loss of the quantum bit, a structure that is long in the deposition direction is formed with the GS.

Accordingly, it is possible to configure the superconducting quantum circuit 1 such that a JJ due to a long opening in the deposition direction does not occur.

A boundary portion of the GS and the SES needs to consider position shift due to oblique deposition.

For this reason, each stretched end 32e is provided with an overlap margin that is long in the X direction with respect to the overlap portion, in consideration of the superconductor being deposited to be shifted in the X direction by oblique deposition.

That is, in the example of the superconducting quantum circuit 1 of the present example embodiment, the stretched end 32e further extends in the X direction than the overlap portion.

For example, in the superconducting quantum circuit 1, as illustrated in FIGS. 1 and 2, in the overlap portion of the second deposition pattern 51A and the stretched end 32e of the protrusion pattern 32A that is a connection portion of the SES and the GS on the left side of the SQUID, an overlap margin that is long in the X direction with respect to the overlap portion is provided.

For example, as illustrated in FIGS. 1 and 2, in the example of the superconducting quantum circuit 1, an overlap margin that is long in the X direction with respect to the overlap portion is also provided in the overlap portion of the first deposition pattern 41A and the stretched end 32e of the island pattern 32B.

With the superconducting quantum circuit 1 of the present example embodiment, the protrusion pattern 32A of the superconductor layer 3 protrudes and extends from the surface pattern 31 to the first deposition pattern 41 and the second deposition pattern 51.

With this, it is possible to replace a portion in each deposition pattern extending toward the surface pattern 31 with a pattern of the superconductor layer 3.

For this reason, it is possible to configure the first deposition layer 4 and the second deposition layer 5 such that each deposition pattern is shortened.

Accordingly, the superconducting quantum circuit 1 is easily formed with the deposition patterns.

With the superconducting quantum circuit 1 of the present example embodiment, the island pattern 32B of the superconductor layer 3 is separated from the surface pattern 31.

With this, it is possible to replace a portion different from the portion in each deposition pattern toward the surface pattern 31 with a pattern of the superconductor layer 3.

For this reason, it is possible to configure the first deposition layer 4 and the second deposition layer 5 such that each deposition pattern is shortened.

Accordingly, the superconducting quantum circuit 1 is easily formed with the deposition patterns.

With the superconducting quantum circuit 1 of the present example embodiment, the stretched pattern 32 extends in the X direction that is a direction intersecting the connection direction D2.

With this, it is possible to replace at least a part of a portion in the deposition pattern extending while intersecting the connection direction D2 with a pattern of the superconductor layer 3.

For this reason, it is possible to configure the first deposition layer 4 and the second deposition layer 5 such that the deposition patterns are shortened.

Accordingly, the superconducting quantum circuit 1 is easily formed with the deposition patterns.

In the superconducting quantum circuit 1 of the present example embodiment, the SQUID 81 is configured.

For this reason, the resonant frequency can be changed with adjustment of the inductance of the SQUID 81 by making a direct current flow in a pump line coupled to the SQUID 81 or the like.

In the superconducting quantum circuit 1 of the present example embodiment, the nonlinear inductor 8 including the SQUID 81 is configured.

According to such a configuration, the SQUID 81 is handled as variable inductance, so that the superconducting quantum circuit 1 can be excited in a resonance mode with nonlinearity. If there is nonlinearity, a transition frequency of a ground state (|0>) and a first excited state (|1>) and a transition frequency of other states (|2> or more) of a resonator are different. Therefore, the superconducting quantum circuit 1 can be handled as a system having only two states of |0>/|1>, that is, a quantum bit.

With the manufacturing method of the present example embodiment, in the superconducting quantum circuit 1 to be manufactured, the stretched patterns 32 of the superconductor layer 3 extend to the first deposition pattern 41 and the second deposition pattern 51.

For this reason, in the superconducting quantum circuit 1 to be manufactured, it is possible to configure the first deposition layer 4 and the second deposition layer 5 such that the first deposition pattern 41 and the second deposition pattern 51 are shortened.

Accordingly, with the manufacturing method, the superconducting quantum circuit 1 is easily formed with the deposition patterns.

Hereinafter, some example embodiments according to the present disclosure will be described with reference to the drawings.

A superconducting quantum circuit 101 of the present example embodiment has a similar configuration, operates similarly, is manufactured similarly, and has similar operation and effects to the superconducting quantum circuit 1 of some example embodiments described above, excluding the following points.

For example, a plurality of stretched patterns 32 of the present example embodiment may include a pair of protrusion patterns 132A and an island pattern 132B instead of or in addition to the pair of protrusion patterns 32A and the island pattern 32B of some example embodiments described above.

For example, a plurality of first deposition patterns 41 of the present example embodiment may include a first deposition pattern 141A to a first deposition pattern 141D instead of (or in addition to) the first deposition pattern 41A to the first deposition pattern 41D.

For example, a plurality of second deposition patterns 51 of the present example embodiment may include a second deposition pattern 151A to a second deposition pattern 151C instead of (or in addition to) the second deposition pattern 51A to the second deposition pattern 51C.

For example, a plurality of Josephson junctions 6 of the present example embodiment may include a first Josephson junction 106A to a fourth Josephson junction 106D instead of (or in addition to) the first Josephson junction 6A to the fourth Josephson junction 6D.

Specific description will be provided below.

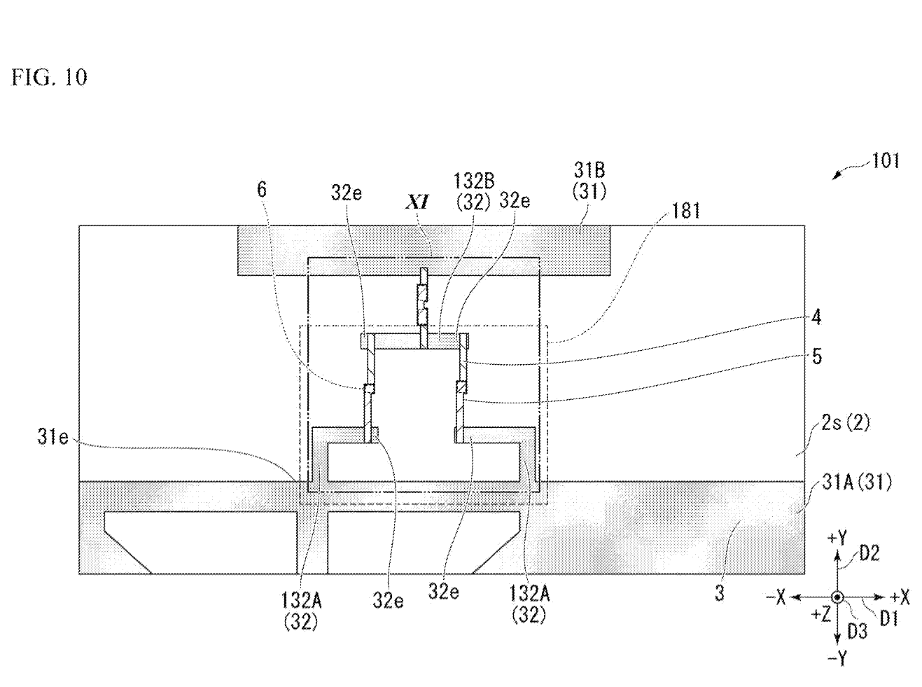

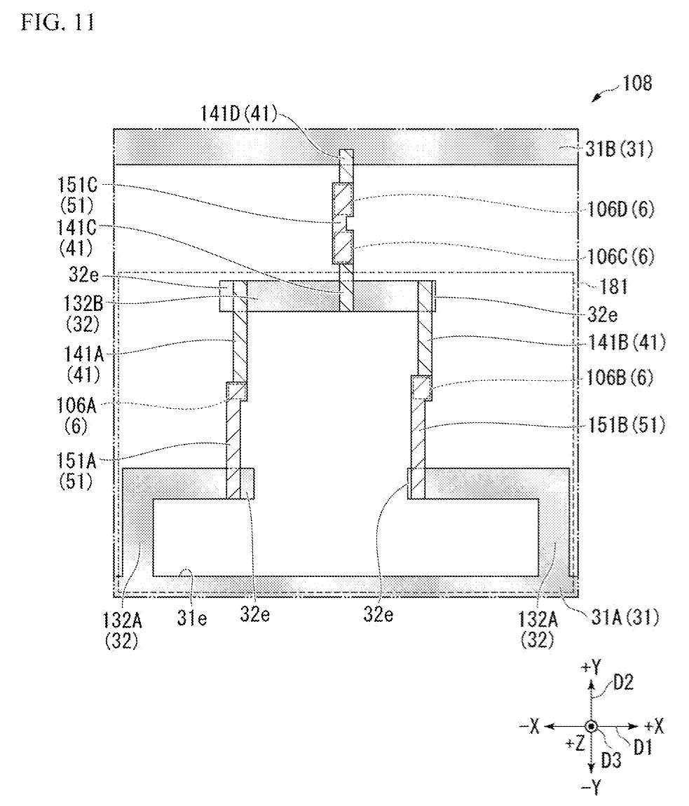

As illustrated in FIG. 10, the superconducting quantum circuit 101 includes a substrate 2, a superconductor layer 3, a first deposition layer 4, and a second deposition layer 5.

The superconducting quantum circuit 101 has a plurality of Josephson junctions 6.

### Configuration of Superconductor Layer

In the superconductor layer 3, a pair of protrusion patterns 132A and an island pattern 132B are included.

Each protrusion pattern 132A is a pattern that is continuous to a ground pattern 31A.

Each protrusion pattern 132A protrudes from the ground pattern 31A in the Y direction to have a stretched end 32e as a protrusion end.

Specifically, the protrusion pattern 132A on the -X direction side out of the pair of protrusion patterns 132A protrudes from the ground pattern 31A in the +Y direction, is bent in the +X direction from a protrusion end in the +Y direction, and further extends in the +X direction.

The protrusion pattern 132A on the +X direction side out of the pair of protrusion patterns 132A protrudes from the ground pattern 31A in the +Y direction, is bent in the -X direction from a protrusion end in the +Y direction, and further extends in the -X direction.

For example, each protrusion pattern 132A may protrude from an end side 31e of the ground pattern 31A extending in the X direction with a width in the X direction smaller than a length of the end side 31e in the X direction.

For example, a portion of each protrusion pattern 132A protruding and extending in the Y direction may have a constant width in the X direction over the whole.

For example, a portion of each protrusion pattern 132A protruding and extending in the X direction may have a constant width in the Y direction over the whole and may be the same as the width in the X direction of the portion of each protrusion pattern 132A protruding in the Y direction.

For example, each protrusion pattern 132A may be, as a whole, an L-shaped pattern that is bent at right angles from the portion protruding and extending in the Y direction to the portion extending in the X direction.

The pair of protrusion patterns 132A may have the same shape and may have the same size.

The island pattern 132B is separated from the plurality of surface patterns 31.

In the present example embodiment, the island pattern 132B is separated from the ground pattern 31A and the electrode pattern 31B.

For example, the island pattern 132B may be separated from the pair of protrusion patterns 132A in the +Y direction.

As viewed from the X direction, for example, the island pattern 132B may be positioned between the ground pattern 31A and the electrode pattern 31B, and may be separated from the ground pattern 31A and the electrode pattern 31B.

As viewed from the Y direction, for example, the island pattern 132B may extend between the pair of protrusion patterns 132A facing each other such that both ends of the island pattern 132B overlap the protrusion ends of the pair of protrusion patterns 132A facing each other.

For example, the island pattern 132B may have the same width in the Y direction as the width in the Y direction of the portion of each protrusion pattern 132A protruding and extending in the X direction.

### Configuration of First Deposition Layer

The first deposition layer 4 is a pattern for bridging the ground pattern 31A, the island pattern 132B, and the electrode pattern 31B via the Josephson junctions 6 along with the second deposition layer 5.

As illustrated in FIG. 11, in the first deposition layer 4, for example, a plurality of first deposition patterns 41 may include a first deposition pattern 141A, a first deposition pattern 141B, a first deposition pattern 141C, and a first deposition pattern 141D.

Each of the first deposition pattern 141A, the first deposition pattern 141B, the first deposition pattern 141C, and the first deposition pattern 141D has a band shape extending in the Y direction.

The first deposition pattern 141A and the first deposition pattern 141B are positioned at the center in the Y direction and are arranged in the X direction separately from each other.

A portion of the first deposition pattern 141A on the +Y direction side is electrically connected to the island pattern 132B by overlapping the stretched end 32e of the island pattern 132B on the -X direction side.

For example, with respect to an overlap portion of the first deposition pattern 141A and the stretched end 32e of the island pattern 132B, the stretched end 32e of the island pattern 132B on the -X direction side may further extend from the overlap portion in the -X direction.

A portion of the first deposition pattern 141B on the +Y direction side is electrically connected to the island pattern 132B by overlapping the stretched end 32e of the island pattern 132B on the +X direction side.

For example, with respect to an overlap portion of the first deposition pattern 141B and the stretched end 32e of the island pattern 132B, the stretched end 32e of the island pattern 132B on the +X direction side may further extend from the overlap portion in the +X direction.

The first deposition pattern 141C and the first deposition pattern 141D are positioned on the +Y direction side with respect to the first deposition pattern 141A and the first deposition pattern 141B.

The first deposition pattern 141C and the first deposition pattern 141D are arranged in the Y direction separately from each other.

As viewed from the Y direction, the first deposition pattern 141C and the first deposition pattern 141D are positioned between the first deposition pattern 141A and the first deposition pattern 141B, and are separated from the first deposition pattern 141A and the first deposition pattern 141B.

A portion of the first deposition pattern 141C on the -Y direction side is electrically connected to the island pattern 132B by overlapping a central portion of the island pattern 132B in the X direction.

A portion of the first deposition pattern 141D on the +Y direction side is electrically connected to the electrode pattern 31B by overlapping a central portion of the electrode pattern 31B in the X direction.

### Configuration of Second Deposition Layer

In the second deposition layer 5, for example, a plurality of second deposition patterns 51 may include a second deposition pattern 151A, a second deposition pattern 151B, and a second deposition pattern 151C.

Each of the second deposition pattern 151A, the second deposition pattern 151B, and the second deposition pattern 151C has a band shape extending in the Y direction.

The second deposition pattern 151A and the second deposition pattern 151B are positioned on the -Y direction side with respect to the first deposition pattern 141A and the first deposition pattern 141B.

The second deposition pattern 151A and the second deposition pattern 151B are arranged in the X direction separately from each other.

The second deposition pattern 151A partially overlaps the first deposition pattern 141A to be shifted in the -Y direction with respect to the first deposition pattern 141A.

The second deposition pattern 151B partially overlaps the first deposition pattern 141B to be shifted in the -Y direction with respect to the first deposition pattern 141B.

A portion of the second deposition pattern 151A on the -Y direction side is electrically connected to the protrusion pattern 132A on the -X direction side by overlapping a portion of the stretched end 32e of the protrusion pattern 132A on the -X direction side out of the pair of protrusion patterns 132A.

For example, with respect to an overlap portion of the second deposition pattern 151A and the stretched end 32e of the protrusion pattern 132A, the stretched end 32e of the protrusion pattern 132A on the -X direction side may further extend from the overlap portion in the +X direction.

A portion of the second deposition pattern 151A on the +Y direction side is electrically connected to the first deposition pattern 141A via the Josephson junction 6 by overlapping a portion of the first deposition pattern 141A on the -Y direction side.

For example, the width in the X direction of the portion of the second deposition pattern 151A on the +Y direction side may be wider than the width in the X direction of another portion of the second deposition pattern 151A in the portion overlapping the first deposition pattern 141A.

For example, a width in the X direction of the portion of the second deposition pattern 151A on the -Y direction side may be wider than a width in the X direction of the first deposition pattern 141A in the portion overlapping the first deposition pattern 141A.

A portion of the second deposition pattern 151B on the -Y direction side is electrically connected to the protrusion pattern 132A on the +X direction side by overlapping a portion of the stretched end 32e of the protrusion pattern 132A on the +X direction side out of the pair of protrusion patterns 132A.

For example, with respect to an overlap portion of the second deposition pattern 151B and the stretched end 32e of the protrusion pattern 132A, the stretched end 32e of the protrusion pattern 132A on the +X direction side may further extend from the overlap portion in the -X direction.

A portion of the second deposition pattern 151B on the +Y direction side is electrically connected to the first deposition pattern 141B via the Josephson junction 6 by overlapping a portion of the first deposition pattern 141B on the -Y direction side.

For example, the width in the X direction of the portion of the second deposition pattern 151B on the +Y direction side may be wider than the width in the X direction of another portion of the second deposition pattern 151B in the portion overlapping the first deposition pattern 141B.

For example, the width in the X direction of the portion of the second deposition pattern 151B on the +Y direction side may be wider than the width in the X direction of the first deposition pattern 141B in the portion overlapping the first deposition pattern 141B.

The second deposition pattern 151C partially overlaps the first deposition pattern 141C to be shifted in the +Y direction with respect to the first deposition pattern 141C.

A portion of the second deposition pattern 151C on the -Y direction side is electrically connected to the first deposition pattern 141C via the Josephson junction 6 by overlapping a portion of the first deposition pattern 141C on the +Y direction side.

For example, the width in the X direction of the portion of the second deposition pattern 151C on the -Y direction side may be wider than the width in the X direction of a central portion of the second deposition pattern 151C in the Y direction in the portion overlapping the first deposition pattern 141C.

For example, the width in the X direction of the portion of the second deposition pattern 151C on the -Y direction side may be wider than the width in the X direction of the first deposition pattern 141C in the portion overlapping the first deposition pattern 141C.

The second deposition pattern 151C partially overlaps the first deposition pattern 141D to be shifted in the -Y direction with respect to the first deposition pattern 141D.

A portion of the second deposition pattern 151C on the +Y direction side is electrically connected to the first deposition pattern 141D via the Josephson junction 6 by overlapping a portion of the first deposition pattern 141D on the -Y direction side.

For example, a width in the X direction of the portion of the second deposition pattern 151C on the +Y direction side may be wider than the width in the X direction of the central portion of the second deposition pattern 151C in the Y direction in the portion overlapping the first deposition pattern 141D.

For example, the width in the X direction of the portion of the second deposition pattern 151C on the +Y direction side may be wider than a width in the X direction of the first deposition pattern 141D in the portion overlapping the first deposition pattern 141D.

### Configuration of Josephson Junction

In the present example embodiment, a plurality of Josephson junctions 6 include a first Josephson junction 106A, a second Josephson junction 106B, a third Josephson junction 106C, and a fourth Josephson junction 106D.

The first Josephson junction 106A is formed in a portion where the first deposition pattern 141A overlaps the second deposition pattern 151A.

The second Josephson junction 106B is formed in a portion where the first deposition pattern 141B overlaps the second deposition pattern 151B.

The third Josephson junction 106C is formed in a portion where the first deposition pattern 141C overlaps the second deposition pattern 151C.

The fourth Josephson junction 106D is formed in a portion where the first deposition pattern 141D overlaps the second deposition pattern 151C.

### Configuration of Nonlinear Inductor and Superconducting Quantum Interference Device

In the superconducting quantum circuit 101, the superconductor layer 3, the first deposition patterns 41, the second deposition patterns 51, and the Josephson junctions 6 are electrically connected to configure a SQUID 181.

A nonlinear inductor 108 includes the SQUID 181.

The nonlinear inductor 108 and the SQUID 181 are specifically configured as follows.

The SQUID 181 includes the pair of protrusion patterns 132A, a pattern of a part of the ground pattern 31A, the island pattern 132B, the first deposition pattern 141A, the first deposition pattern 141B, the second deposition pattern 151A, the second deposition pattern 151B, the first Josephson junction 106A, and the second Josephson junction 106B.

In the SQUID 181, one of the pair of protrusion patterns 132A, the second deposition pattern 151A, the first Josephson junction 106A, the first deposition pattern 141A, the island pattern 132B, the first deposition pattern 141B, the second Josephson junction 106B, the second deposition pattern 151B, the other of the pair of protrusion patterns 132A, and the ground pattern 31A are electrically connected to draw a loop in this order.

The nonlinear inductor 108 includes, in addition to the SQUID 181, the first deposition pattern 141C, the third Josephson junction 106C, the second deposition pattern 151C, the fourth Josephson junction 106D, the first deposition pattern 141D, and the electrode pattern 31B.

In the nonlinear inductor 108, the SQUID 181 and the third Josephson junction 106C are electrically connected in series via the first deposition pattern 141C.

In the nonlinear inductor 108, the third Josephson junction 106C and the fourth Josephson junction 106D are electrically connected in series via the second deposition pattern 151C.

In the nonlinear inductor 108, the fourth Josephson junction 106D and the electrode pattern 31B are electrically connected in series via the first deposition pattern 141D.

### Operation and Effects

With the superconducting quantum circuit 101 of the present example embodiment, the stretched pattern 32 of the superconductor layer 3 extends to the first deposition pattern 41 and the second deposition pattern 51.

For this reason, it is possible to configure the first deposition layer 4 and the second deposition layer 5 such that the first deposition pattern 41 and the second deposition pattern 51 are shortened.

Accordingly, the superconducting quantum circuit 101 is easily formed with the deposition patterns.

With the superconducting quantum circuit 101 of the present example embodiment, the protrusion pattern 132A of the superconductor layer 3 protrudes and extends from the surface pattern 31 to the first deposition pattern 41 and the second deposition pattern 51.

With this, it is possible to replace a portion in each deposition pattern extending toward the surface pattern 31 with a pattern of the superconductor layer 3.

For this reason, it is possible to configure the first deposition layer 4 and the second deposition layer 5 such that each deposition pattern is shortened.

Accordingly, the superconducting quantum circuit 101 is easily formed with the deposition patterns.

With the superconducting quantum circuit 101 of the present example embodiment, the island pattern 132B of the superconductor layer 3 is separated from the surface pattern 31.

With this, it is possible to replace a portion different from the portion in each deposition pattern toward the surface pattern 31 with a pattern of the superconductor layer 3.

For this reason, it is possible to configure the first deposition layer 4 and the second deposition layer 5 such that each deposition pattern is shortened.

Accordingly, the superconducting quantum circuit 101 is easily formed with the deposition pattern.

The superconducting quantum circuit 101 has similar operation and effects to the superconducting quantum circuit 1 and the manufacturing method described above.

In addition, with the superconducting quantum circuit 101 of the present example embodiment, the stretched pattern 32 extends in the Y direction that is the connection direction D2.

For this reason, it is possible to replace at least a part of a portion in the deposition pattern extending in the connection direction D2 with a pattern of the superconductor layer 3.

For this reason, it is possible to configure the first deposition layer 4 and the second deposition layer 5 such that the deposition patterns are shortened.

Accordingly, the superconducting quantum circuit 101 is easily formed with the deposition patterns.

### Modification Examples

In each example embodiment described above, while the superconductor layer 3 includes the surface pattern 31 as a main pattern, the main pattern may be any pattern as long as the pattern is laminated over the substrate surface 2s. As a modification example, the main pattern may be a linear pattern, not a planar pattern.

In each example embodiment described above, while the stretched patterns 32 of the superconductor layer 3 extend to the first deposition pattern 41 and the second deposition pattern 51, any configuration may be made as long as the deposition patterns can be shortened.

As a modification example, the stretched pattern 32 of the superconductor layer 3 may extend to at least one of the first deposition pattern 41 and the second deposition pattern 51.

Also, according to such a modification example, since the deposition patterns can be shortened, the superconducting quantum circuit is easily formed with the deposition patterns.

In each example embodiment described above, the second deposition layer 5 is partially laminated on the first deposition layer 4 by the oblique deposition method. Note that the second deposition layer 5 may be partially laminated on the first deposition layer 4 by any method as long as the Josephson junction 6 can be formed.

If the deposition pattern can be shortened without depending on the configuration of the Josephson junction or the deposition method, the superconducting quantum circuit is easily formed with the deposition pattern.

In each example embodiment described above, while the nonlinear inductor includes a SQUID and a pair of Josephson junctions, any configuration may be made as long as the nonlinear inductor can be configured.

As a modification example, the nonlinear inductor may include a plurality of SQUIDs and a plurality of pairs of Josephson junctions. In this case, a plurality of SQUIDs and a plurality of pairs of Josephson junctions may be connected in any order.

In each example embodiment described above, while the stretched pattern extends in at least one of the X direction and the Y direction, the stretched pattern may extend in any direction as long as the deposition patterns can be shortened.

As a modification example, the stretched pattern may extend in an oblique direction with respect to the X direction and the Y direction.

Also, according to such a modification example, since the deposition patterns can be shortened, the superconducting quantum circuit is easily formed with the deposition patterns.

In each example embodiment described above, while the second deposition layer 5 is partially laminated over the first deposition layer 4, as a modification example, the first deposition layer 4 may be partially laminated over the second deposition layer 5.

Also, according to such a modification example, since the deposition patterns can be shortened, the superconducting quantum circuit is easily formed with the deposition patterns.

In each example embodiment described above, while the second deposition pattern 51 is electrically connected to the protrusion pattern by overlapping a portion of the stretched end 32e of the protrusion pattern, any configuration may be made as long as at least one of the first deposition pattern 41 and the second deposition pattern 51 is electrically connected to the protrusion pattern.

As a modification example, the first deposition pattern 41 that is electrically connected to the second deposition pattern 51 via the Josephson junction 6 may be electrically connected to the protrusion pattern by overlapping a portion of the stretched end 32e of the protrusion pattern.

Also, according to such a modification example, since the deposition patterns can be shortened, the superconducting quantum circuit is easily formed with the deposition patterns.

In each example embodiment described above, while the second deposition pattern 51 is electrically connected to the protrusion pattern by overlapping a portion of the stretched end 32e of the protrusion pattern, any configuration may be made as long as at least one of the first deposition pattern 41 and the second deposition pattern 51 is electrically connected to the protrusion pattern.

As a modification example, the second deposition pattern 51 may be electrically connected to the protrusion pattern by overlapping a portion (for example, a portion in the protrusion pattern on a position closer to the end side 31e from the stretched end 32e) other than the stretched end 32e of the protrusion pattern.

As another modification example, the first deposition pattern 41 may be electrically connected to the protrusion pattern by overlapping a portion (for example, a portion in the protrusion pattern on a position closer to the end side 31e from the stretched end 32e) other than the stretched end 32e of the protrusion pattern.

Also, according to such a modification example, since the deposition patterns can be shortened, the superconducting quantum circuit is easily formed with the deposition patterns.

In each example embodiment described above, while the first deposition pattern 41 is electrically connected to the island pattern by overlapping a portion of the stretched end 32e of the island pattern, any configuration may be made as long as at least one of the first deposition pattern 41 and the second deposition pattern 51 is electrically connected to the island pattern.

As a modification example, the second deposition pattern 51 that is electrically connected to the first deposition pattern 41 via the Josephson junction 6 may be electrically connected to the island pattern by overlapping a portion of the stretched end 32e of the island pattern.

Also, according to such a modification example, since the deposition patterns can be shortened, the superconducting quantum circuit is easily formed with the deposition patterns.

In each example embodiment described above, while the first deposition pattern 41 is electrically connected to the island pattern by overlapping the stretched end 32e of the island pattern, any configuration may be made as long as at least one of the first deposition pattern 41 and the second deposition pattern 51 is electrically connected to the island pattern.

As a modification example, the first deposition pattern 41 may be electrically connected to the island pattern by overlapping a portion (for example, a portion in the island pattern between the stretched end 32e and the stretched end 32e) other than the stretched ends 32e of the island pattern.

As another modification example, the second deposition pattern 51 may be electrically connected to the island pattern by overlapping a portion (for example, a portion in the island pattern between the stretched end 32e and the stretched end 32e) other than the stretched ends 32e of the island pattern.

Since the deposition pattern can also be shortened by such a modification example, the superconducting quantum circuit is easily formed with the deposition patterns.

Hereinafter, some example embodiments of the present disclosure will be described with reference to the drawings.

### Configuration of Superconducting Quantum Circuit

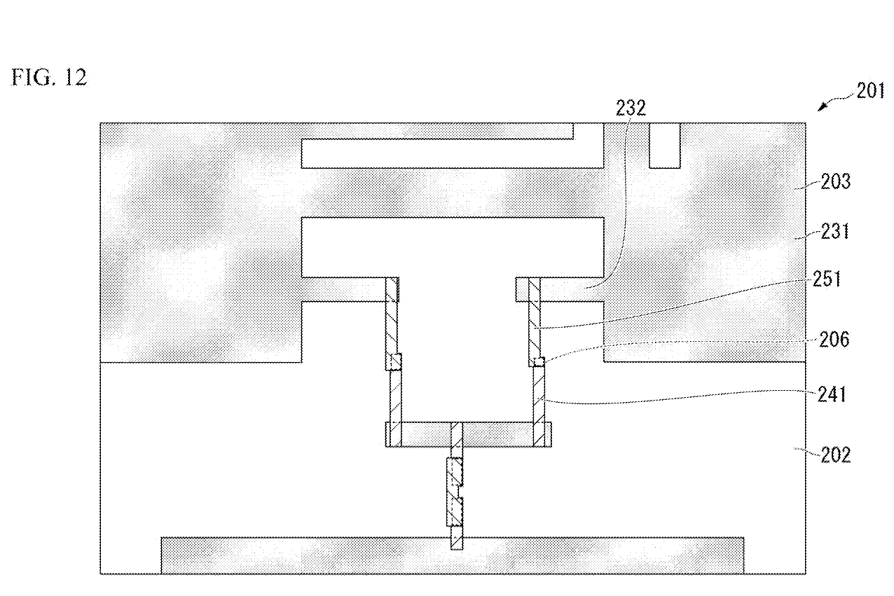

As illustrated in FIG. 12, a superconducting quantum circuit 201 of the present example embodiment includes a substrate 202, a superconductor layer 203, a first deposition pattern 241, and a second deposition pattern 251.

The superconductor layer 203 is laminated on the substrate 202 and includes a main pattern 231 and a stretched pattern 232.

A portion of the first deposition pattern 241 is laminated on the superconductor layer 203.

A portion of the second deposition pattern 251 is laminated on a first deposition layer 204.

A superconducting quantum circuit 201 has a Josephson junction 206 in an overlap portion of the first deposition pattern 241 and the second deposition pattern 251.

The stretched pattern 232 and at least one of the first deposition pattern 241 and the second deposition pattern 251 are connected.

### Operation and Effects

With the superconducting quantum circuit 201 of the present example embodiment, the stretched pattern 232 of the superconductor layer 203 extends to at least one of the first deposition pattern 241 and the second deposition pattern 251.

For this reason, it is possible to configure at least one of the first deposition layer 204 and a second deposition layer 205 such that a pattern of at least one of the first deposition pattern 241 and the second deposition pattern 251 is shortened.

Accordingly, the superconducting quantum circuit 201 is easily formed with the deposition patterns.

Hereinafter, some example embodiments according to the present disclosure will be described with reference to the drawings.

### Steps of Manufacturing Method

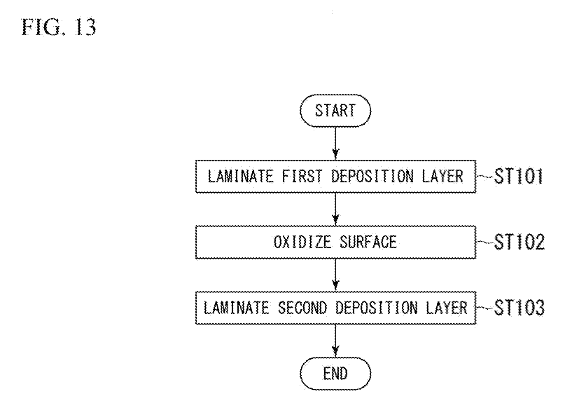

As illustrated in FIG. 13, first, a portion of the first deposition pattern is laminated on the superconductor layer that is laminated on the substrate and includes the main pattern and the stretched pattern (ST101).

The surface of the first deposition pattern is oxidized (ST102: surface oxidization step).

A portion of the second deposition pattern is laminated on the first deposition pattern (ST103).

The Josephson junction is formed in the overlap portion of the first deposition pattern and the second deposition pattern.

The stretched pattern and at least one of the first deposition pattern and the second deposition pattern are connected.

### Operation and Effects

With the manufacturing method of the present example embodiment, in the superconducting quantum circuit to be manufactured, the stretched pattern of the superconductor layer extends to at least one of the first deposition pattern and the second deposition pattern.

For this reason, in the superconducting quantum circuit to be manufactured, it is possible to configure at least one of the first deposition layer and the second deposition layer such that a pattern of at least one of the first deposition pattern and the second deposition pattern is shortened.

Accordingly, the manufacturing method easily forms the superconducting quantum circuit with the deposition patterns.

While preferred example embodiments of the disclosure have been described and illustrated above, it should be understood that these are exemplary of the disclosure and are not to be considered as limiting. Additions, omissions, substitutions, and other modifications can be made without departing from the spirit or scope of the present disclosure. Accordingly, the disclosure is not to be considered as being limited by the foregoing description, and is only limited by the scope of the appended claims.

According to the above-described example aspect, the superconducting quantum circuit is easily formed with the deposition patterns.

A part or the whole of the several example embodiments described above can be described as, but are not limited to, the following supplementary notes.

### Supplementary Note 1

A superconducting quantum circuit including a substrate, a superconductor layer that is laminated on the substrate and includes a main pattern and a stretched pattern, a first deposition pattern having a portion that is laminated on the superconductor layer, a second deposition pattern having an overlap portion with the first deposition pattern, and a Josephson junction in the overlap portion, in which the stretched pattern is connected with at least one of the first deposition pattern or the second deposition pattern.

### Supplementary Note 2

The superconducting quantum circuit according to Supplementary Note 1, in which the stretched pattern protrudes from the main pattern.

### (Supplementary Note 3)

The superconducting quantum circuit according to Supplementary Note 1, in which the stretched pattern is separated from the main pattern.

### Supplementary Note 4

The superconducting quantum circuit according to any one of Supplementary Notes 1 to 3, in which the first deposition pattern and the second deposition pattern are shifted from each other in a connection direction, and in which the stretched pattern extends in a direction intersecting the connection direction.

### Supplementary Note 5

The superconducting quantum circuit according to any one of Supplementary Notes 1 to 3, in which the first deposition pattern and the second deposition pattern are shifted from each other in a connection direction, and in which the stretched pattern extends in the connection direction.

### Supplementary Note 6

The superconducting quantum circuit according to any one of Supplementary Notes 1 to 5, in which the superconductor layer, the first deposition pattern, the second deposition pattern, and the Josephson junction are connected to configure a superconducting quantum interference device.

### Supplementary Note 7

The superconducting quantum circuit according to Supplementary Note 6, further comprising a nonlinear inductor including the superconducting quantum interference device.

### Supplementary Note 8

A quantum bit including

the superconducting quantum circuit according to any one of Supplementary Notes 1 to 7, and a coupling portion configured to be connected to a coupler.

### Supplementary Note 9

A quantum computer including the quantum bit according to Supplementary Note 8, and the coupler, in which the quantum bit includes a first quantum bit and a second quantum bit, and in which the coupler connects the coupling portion of the first quantum bit and the coupling portion of the second quantum bit.

### (Supplementary Note 10)

A manufacturing method including laminating a portion of a first deposition pattern on a superconductor layer that is laminated on a substrate and includes a main pattern and a stretched pattern, oxidizing a surface of the first deposition pattern, and forming a second deposition pattern, in which a Josephson junction is formed in an overlap portion of the first deposition pattern and the second deposition pattern, and in which the stretched pattern is connected with at least one of the first deposition pattern or the second deposition pattern.

### Supplementary Note 11

The manufacturing method according to Supplementary Note 10, in which the stretched pattern protrudes from the main pattern.

### Supplementary Note 12

The manufacturing method according to Supplementary Note 10 or 11, in which the stretched pattern is separated from the main pattern.

### Supplementary Note 13

The manufacturing method according to any one of Supplementary Notes 10 to 12, in which the first deposition pattern and the second deposition pattern are shifted from each other in a connection direction, and in which the stretched pattern extends in a direction intersecting the connection direction.

### Supplementary Note 14

The manufacturing method according to any one of Supplementary Notes 10 to 12, in which the first deposition pattern and the second deposition pattern are shifted from each other in a connection direction, and in which the stretched pattern extends in the connection direction.

### Supplementary Note 15

The manufacturing method according to any one of Supplementary Notes 10 to 14, in which the superconductor layer, the first deposition pattern, the second deposition pattern, and the Josephson junction are connected to configure a superconducting quantum interference device.

### Supplementary Note 16

The manufacturing method according to Supplementary Note 15, in which a nonlinear inductor including the superconducting quantum interference device is configured.

What is claimed is:

1. A superconducting quantum circuit comprising:
a substrate;
a superconductor layer that is laminated on the substrate and includes a main pattern and a stretched pattern;
a first deposition pattern having a portion that is laminated on the superconductor layer;
a second deposition pattern having an overlap portion with the first deposition pattern; and
a Josephson junction in the overlap portion,
wherein the stretched pattern is connected with at least one of the first deposition pattern or the second deposition pattern.

2. The superconducting quantum circuit according to claim 1,
wherein the stretched pattern protrudes from the main pattern.

3. The superconducting quantum circuit according to claim 1,
wherein the stretched pattern is separated from the main pattern.

4. The superconducting quantum circuit according to claim 1,
wherein the first deposition pattern and the second deposition pattern are shifted from each other in a connection direction, and
wherein the stretched pattern extends in a direction intersecting the connection direction.

5. The superconducting quantum circuit according to claim 1,
wherein the first deposition pattern and the second deposition pattern are shifted from each other in a connection direction, and
wherein the stretched pattern extends in the connection direction.

6. The superconducting quantum circuit according to claim 1,
wherein the superconductor layer, the first deposition pattern, the second deposition pattern, and the Josephson junction are connected to configure a superconducting quantum interference device.

7. The superconducting quantum circuit according to claim 6, further comprising a nonlinear inductor including the superconducting quantum interference device.

8. A quantum bit comprising:
the superconducting quantum circuit according to claim 1; and
a coupling portion configured to be connected to a coupler.

9. A quantum computer comprising:
the quantum bit according to claim 8; and
the coupler,
wherein the quantum bit includes a first quantum bit and a second quantum bit, and
wherein the coupler connects the coupling portion of the first quantum bit and the coupling portion of the second quantum bit.

10. A manufacturing method comprising:
laminating a portion of a first deposition pattern on a superconductor layer that is laminated on a substrate and includes a main pattern and a stretched pattern;
oxidizing a surface of the first deposition pattern; and
forming a second deposition pattern,
wherein a Josephson junction is formed in an overlap portion of the first deposition pattern and the second deposition pattern, and
wherein the stretched pattern is connected with at least one of the first deposition pattern or the second deposition pattern.

11. The manufacturing method according to claim 10,
wherein the stretched pattern protrudes from the main pattern.

12. The manufacturing method according to claim 10,
wherein the stretched pattern is separated from the main pattern.

13. The manufacturing method according to claim 10,
wherein the first deposition pattern and the second deposition pattern are shifted from each other in a connection direction, and
wherein the stretched pattern extends in a direction intersecting the connection direction.

14. The manufacturing method according to claim 10,
wherein the first deposition pattern and the second deposition pattern are shifted from each other in a connection direction, and
wherein the stretched pattern extends in the connection direction.

15. The manufacturing method according to claim 10,
wherein the superconductor layer, the first deposition pattern, the second deposition pattern, and the Josephson junction are connected to configure a superconducting quantum interference device.

16. The manufacturing method according to claim 15,
wherein a nonlinear inductor including the superconducting quantum interference device is configured.
